(19) United States
(12) Patent Application Publication
(10) Pub. No.: US 2012/0161595 A1
(43) Pub. Date: Jun. 28, 2012

(54) ELECTRONIC DEVICE ENCLOSURE

(75) Inventors: LI-FU XU, Shenzhen City (CN); ZHI-GUO ZHANG, Shenzhen City (CN); CHAO GENG, Shenzhen City (CN); XIANG ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/179,777

(22) Filed: Jul. 11, 2011

(30) Foreign Application Priority Data
Dec. 28, 2010 (CN) 201010608984.3

(51) Int. Cl. H05K 7/20; H05K 5/02

(52) U.S. Cl. 312/236

(57) ABSTRACT

An electronic device enclosure includes a plate, a securing member, a fan module, and a security apparatus. The plate defines an air vent area and a first through hole. The first through hole is located above the air vent area. The securing member is mounted on an inner side of the plate. The securing member is located above the air vent area. The securing member defines an engaging hole and a second through hole, which is in alignment with the first through hole. The fan module includes a clasp. The fan module is aligned to the air vent area. The clasp engages in the engaging hole to mount the fan module on the securing hole. The security apparatus includes a locking piece and a cord. The locking piece is mounted in the first through hole and the second through hole, and the cord is configured to fasten to an unmovable object.

### BACKGROUND

1. Technical Field

The present disclosure relates to electronic device enclosures, and more particularly to an electronic device with anti theft mechanism.

2. Description of Related Art

Electronic device enclosures, such as computer enclosures, are designed to connect different operating components together in a compact package. The operating components may include a motherboard, a hard drive, and a graphics card, which may be removably attached to the enclosure by friction or a few fasteners for easy replacement. However, these components may be very expensive and contain information stored on a hard drive that can be impossible to replace if lost.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric and exploded view of an embodiment of an electronic device enclosure.

FIG. 2 is similar to FIG. 1, but viewed from another aspect.

FIG. 3 is an isometric and assembled view of the electronic device enclosure of claim 1.

FIG. 4 is another isometric and assembled view of the electronic device enclosure of claim 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

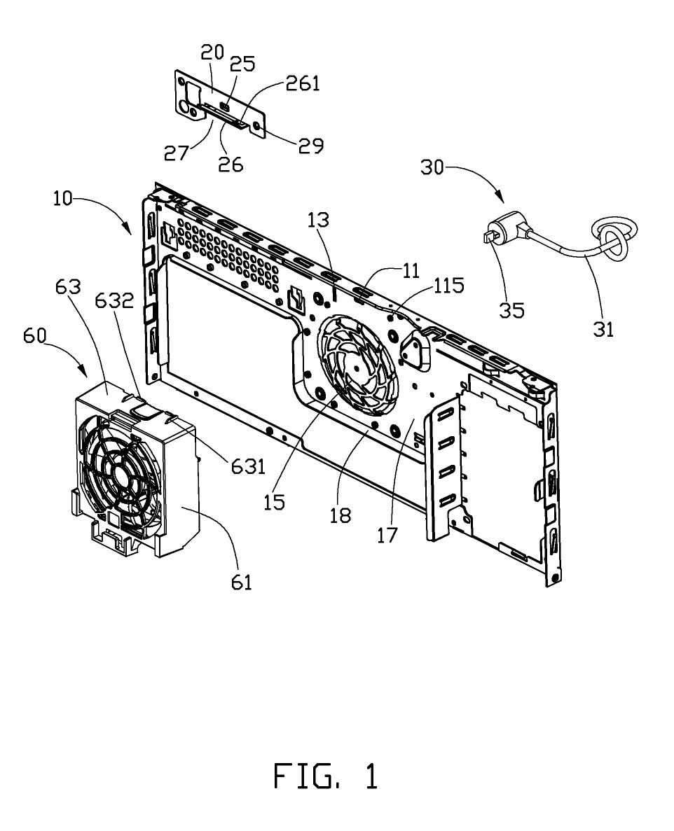

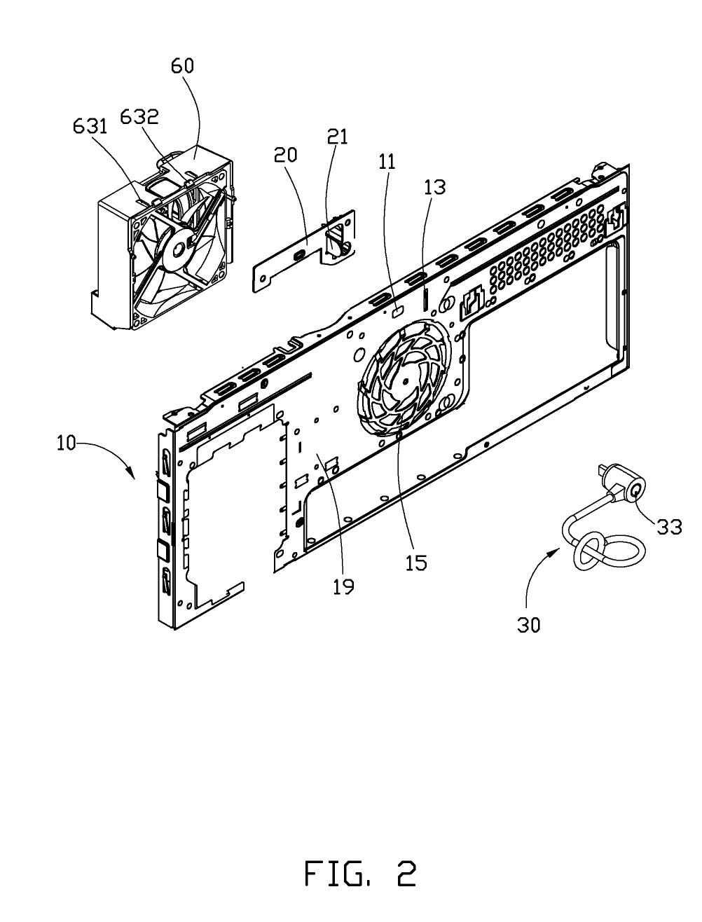

Referring to FIGS. 1 and 2, an electronic device enclosure in accordance with an exemplary embodiment includes a plate 10, a securing member 20, a security apparatus 30, and a fan module 60. The plate 10 is one plate of the electronic device enclosure. The fan module 60 is located in the electronic device enclosure, and can be mounted on an inner side 17 of the plate 10.

The plate 10 defines an air vent area 15 which includes a plurality of air vent holes. The plate 10 defines a first through hole 11, a slot 13, and a plurality of first securing holes 115 above the air vent area 15. A flange 18 is formed below the air vent area 15.

The securing member 20 defines a cutout 27. A top edge of the cutout 27 extends perpendicularly in a first direction to form a mounting piece 26. The mounting piece 26 has two engaging holes 261. A portion of the securing member 20 extends perpendicularly in a second direction, which is reverse to the first direction, to form a positioning piece 21. The securing member 20 defines a plurality of second securing holes 29 corresponding to the first securing holes 115. The securing member 20 defines a second through hole 25 corresponding to the first through hole 11.

The security apparatus 30 includes a cord 31 which can be tied to some unmovable object, such as a post, or a desk. The guiding apparatus 30 further includes a locking piece 35 and a key hole 33. A matching key can be inserted in the key hole 33 to rotate the locking piece 35. A thickness of the locking piece 35 is smaller than the width of the first through hole 11 and the second through hole 25. A width of the locking piece 35 is larger than the width of the first through hole 11 and the second through hole 25.

The fan module 60 includes a frame 61. The frame 61 protects a fan mounted in the frame 61. The frame 61 includes a mounting board 63 which is located on a top side of the frame 61. A pair of restricting pieces 631 is formed on the mounting board 63. A distance between the pair of restricting pieces 631 is approximately equal to the width of the cutout 27. A pair of clasps 632 is located between the pair of restricting pieces 631.

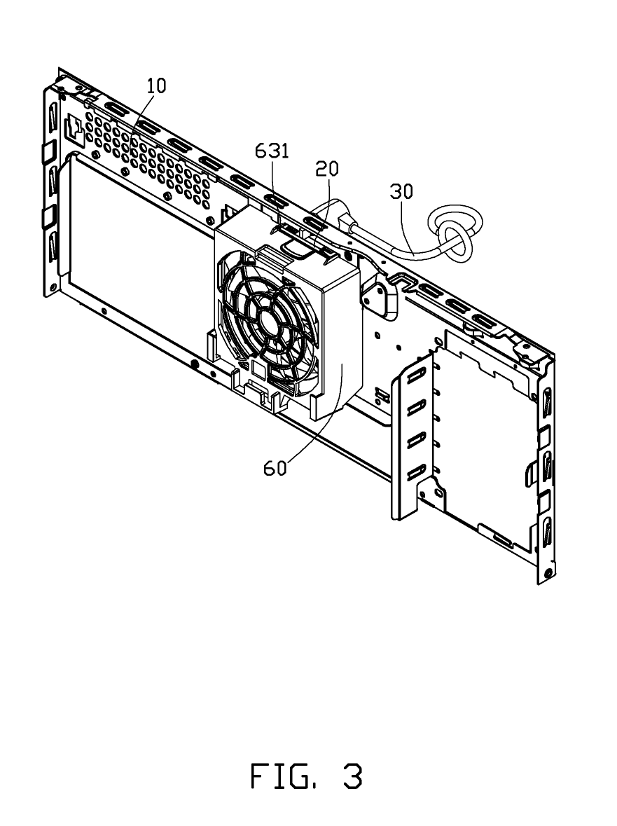

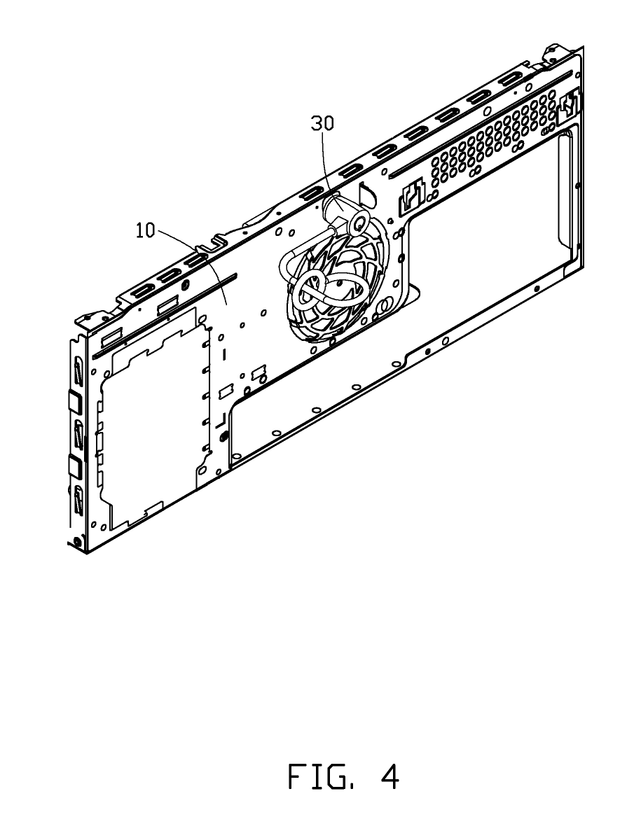

Referring to FIGS. 1 to 4, in assembly, the securing member 20 is aligned to the inner side 17 of the plate 10. The positioning piece 21 of the securing member 20 is inserted in the slot 13 of the plate 10. The second securing holes 29 are in alignment with the first securing holes 115. Fixing members, such as pivots, or screws, are mounted in the first securing holes 115 and the second securing holes 29 to mount the securing member 20 on the inner side 17 of the plate 10. In this position, the second through hole 225 is in alignment with the first through hole 11.

The fan module 60 is aligned to the air vent area 15 of the plate 10 from the inner side 17. The frame 61 of the fan module 60 is located on the flange 18 of the plate 10. The restricting pieces 631 abut opposite edges of the cutout 27. The clasps 632 of the fan module 60 are engaged in the engaging holes 261 of the securing member 20. Therefore, the fan module 60 is secured on the securing member 20.

The locking piece 35 of the security apparatus 30 is inserted in the first through hole 11 and the second through hole 25 from an outer side 19 of the plate 10. Then, a matching key is inserted in the key hole 33 to rotate the locking piece 35. The locking piece 35 does not align with the first through hole 11 and the second through hole 25. Thus, the security apparatus 30 is secured on the plate 10. The cord 31 of the security apparatus 30 is then tied to an unmovable object to secure corresponding electronic device against theft.

In the above electronic device enclosure, the securing member 20 can secure the security apparatus 30 to protect against theft, and also can mount a fan module 60.

It is to be understood, however, that even though numerous characteristics and advantages of the embodiments have been set forth in the foregoing description, together with details of the structure and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device enclosure, comprising:
a plate defining an air vent area and a first through hole, the first through hole located above the air vent area;
a securing member mounted on an inner side of the plate, the securing member located above the air vent area, the securing member defining an engaging hole and a second through hole, the second through hole in alignment with the first through hole;
a fan module comprising a clasp, the fan module aligned to the air vent area, the clasp engaged in the engaging hole to mount the fan module on the securing hole; and
a security apparatus comprising a locking piece and a cord, the locking piece mounted in the first through hole and the second through hole, and the cord is configured to tie to a unmovable object.

2. The electronic device enclosure of claim 1, wherein the plate comprises a flange, which is located below the air vent area, and the fan module is located on the flange.

3. The electronic device enclosure of claim 1, wherein the fan module comprises a mounting board, and the clasp is formed on the mounting board.

4. The electronic device enclosure of claim 3, wherein the mounting board comprises a pair of restricting piece, the securing member defines a cutout, and the pair of restricting pieces abuts opposite edges of the cutout.

5. The electronic device enclosure of claim 1, wherein the securing member comprises a positioning piece, the plate defines a slot, and the positioning piece is inserted in the slot.

6. The electronic device enclosure of claim 5, wherein the securing member comprises a mounting piece, the engaging hole is defined in the mounting piece, a portion of plate extends perpendicularly in a first direction to form the mounting piece, another portion of the securing member extends perpendicularly in a second direction to form the positioning piece, and the first direction is reverse to the second direction.

7. The electronic device enclosure of claim 1, wherein the plate defines a plurality of first securing holes, the securing member defines a plurality of second securing holes, which is aligned to the plurality of first securing holes, and a plurality of fixing members is mounted in the plurality of first securing holes and the plurality of second securing holes to mount the securing member on the inner side of the plate.

8. The electronic device enclosure of claim 1, wherein the locking piece is configured to rotate in the security apparatus between a locking position and a unlocking position; at the locking position, the locking piece is misaligned to the first through hole and the second through hole; and at the unlocking position, the locking piece is aligned to the first through hole and the second through hole.

9. The electronic device enclosure of claim 8, wherein a thickness of the locking piece is smaller than widths of the first through hole and the second through hole, and a width of the locking piece is larger than widths of the first through hole and the second through hole.

10. An electronic device enclosure, comprising:
a plate defining an air vent area and a first through hole, the first through hole located above the air vent area, the plate comprising a flange, the flange located below the air vent area;
a securing member mounted on an inner side of the plate, the securing member located above the air vent area, the securing member defining an engaging hole and a second through hole, the second through hole in alignment with the first through hole;
a fan module comprising a clasp, the fan module aligned to the air vent area, a bottom of the fan module placed on the flange, and the clasp engaged in the engaging hole to mount the fan module on the securing hole; and
a security apparatus comprising a locking piece and a cord, the locking piece mounted in the first through hole and the second through hole, and the cord is configured to tie to a unmovable object.

11. The electronic device enclosure of claim 10, wherein the fan module comprises a mounting board, and the clasp is formed on the mounting board.

12. The electronic device enclosure of claim 11, wherein the mounting board comprises a pair of restricting piece, the securing member defines a cutout, and the pair of restricting pieces abuts opposite edges of the cutout.

13. The electronic device enclosure of claim 10, wherein the securing member comprises a positioning piece, the plate defines a slot, and the positioning piece is inserted in the slot.

14. The electronic device enclosure of claim 13, wherein the securing member comprises a mounting piece, the engaging hole is defined in the mounting piece, a portion of plate extends perpendicularly in a first direction to form the mounting piece, another portion of the securing member extends perpendicularly in a second direction to form the positioning piece, and the first direction is reverse to the second direction.

15. The electronic device enclosure of claim 10, wherein the plate defines a plurality of first securing holes, the securing member defines a plurality of second securing holes, which is aligned to the plurality of first securing holes, and fixing members are mounted in the plurality of first securing holes and the plurality of second securing holes to mount the securing member on the inner side of the plate.

16. The electronic device enclosure of claim 10, wherein the locking piece is configured to rotate in the security apparatus between a locking position and a unlocking position; at the locking position, the locking piece is misaligned to the first through hole and the second through hole; and at the unlocking position, the locking piece is aligned to the first through hole and the second through hole.

17. The electronic device enclosure of claim 16, wherein a thickness of the locking piece is smaller than widths of the first through hole and the second through hole, and a width of the locking piece is larger than widths of the first through hole and the second through hole.
